(19) United States
(12) Patent Application Publication
(10) Pub. No.: US 2012/0168711 A1
(43) Pub. Date: Jul. 5, 2012

(54) Narrow-Waist Nanowire Transistor with Wide Aspect Ratio Ends

(76) Inventors: Mark Albert Crowder, Portland, OR (US); Paul J. Schuele, Washougal, WA (US)

(21) Appl. No.: 12/984,641

(22) Filed: Jan. 5, 2011

(51) Int. Cl. H01L 29/08; H01L 21/84; B82Y 40/00; B82Y 99/00

(52) U.S. Cl. 257/9; 438/151; 977/888; 977/762; 257/E29.04; 257/E21.7

(57) ABSTRACT

A method is provided for forming narrow-waist nanowire (NW) transistors with wide aspect ratio ends. The method provides a semiconductor-on-insulator wafer. The top semiconductor layer is etched to form a first pad, a second pad, and a plurality of narrow-waist semiconductor bridges. Each semiconductor bridge has two ends, each with a first width, attached to the first and second pads, and a mid-section less than the first width. A channel is formed in a center portion of each mid-section, a drain interposed between the channel and the first end, a source interposed between the channel and the second end, and a gate dielectric surrounding the channel and adjacent portions of the source and drain. A gate electrode is formed surrounding the gate dielectric. The semiconductor bridge ends are etched from the first and second pads, forming a plurality of narrow-waist semiconductor NW transistors.

### BACKGROUND OF THE INVENTION

1. Field of the Invention

This invention generally relates to integrated circuit (IC) fabrication and, more particularly, to the fabrication of a narrow-waist nanowire transistor.

2. Description of the Related Art

The common definition of a nanowire (NW) is a cylindrical nanostructure, with the diameter on the order of a nanometer (nm). Alternatively, nanowires can be defined as structures that have a thickness or diameter constrained to tens of nanometers or less and an unconstrained length. At these scales, Wikipedia notes that quantum mechanical effects are important. Many different types of nanowires exist, including metallic (e.g., Ni, Pt, Au), semiconducting (e.g., Si, InP, GaN, etc.), and insulating (e.g., SiO₂, TiO₂). Typical nanowires exhibit aspect ratios (length-to-width ratio) of 1000 or more. Nanowires have many interesting properties that are not seen in bulk materials. This is because electrons in nanowires are quantum confined laterally and thus occupy energy levels that are different from the traditional continuum of energy levels or bands found in bulk materials.

There are two basic approaches of synthesizing nanowires: top-down and bottom-up approach. In a top-down approach a large piece of material is cut down to small pieces through lithography and etching. Whereas in a bottom-up approach the nanowire is synthesized by the combination of constituent ad-atoms. Most of the currently used synthesis techniques are based on a bottom-up approach.

Nanowires also show other peculiar electrical properties due to their size. Unlike carbon nanotubes, whose motion of electrons can fall under the regime of ballistic transport (meaning the electrons can travel freely from one electrode to the other), nanowire conductivity is strongly influenced by edge effects. The edge effects come from atoms that lay at the nanowire surface and are not fully bonded to neighboring atoms like the atoms within the bulk of the nanowire. The unbonded atoms are often a source of defects within the nanowire, and may cause the nanowire to conduct electricity more poorly than the bulk material. As a nanowire shrinks in size, the surface atoms become more numerous compared to the atoms within the nanowire, and edge effects become more important.

Furthermore, the conductivity can undergo a quantization in energy: i.e. the energy of the electrons going through a nanowire can assume only discrete values, multiple of the Von Klitzing constant G=2e²/h (where e is the charge of the electron and h is the Planck constant). The quantized conductivity is more pronounced in semiconductors like Si or GaAs than in metals, due to lower electron density and lower effective mass. Quantized conductance can be observed in 25 nm wide silicon wires, resulting in increased threshold voltage.

Si nanowires have been shown to be useful for fabricating microelectronic devices. This stems from the availability of high temperature processes that can be utilized with the NWs on standard substrates, permitting high quality thermal oxides to be grown, as well as opening the possibility for other process steps such as atomic layer deposition (ALD) for the formation of shell electrodes. As noted above, a number of means for fabricating Si NWs exist, including growth processes such as VLS (vapor-liquid-solid) or etched processes on SOI wafers. Regardless of the means of NW formation, after they are harvested and put into an “ink”, they can be dispersed onto a final substrate for device formation. This is typically done using an e-field process that uses dielectrophoresis (DEP) to place the NWs in specific location on the substrate.

It is difficult to control the number of NWs that are deposited at each set of electrodes and the coating yield, due to a narrow window associated with DEP process. Another issue that has plagued the Si NW fabrication process is poor contact resistance between the NW and any final metal process that contacts the source and drain region of the device. With etched NW processes, an outer shell electrode that is deposited with a PECVD process has a nonuniform step coverage, resulting in thicker material being deposited on the top of the NW, and tapering off as the coverage extends to the bottom of the NW. With a conventionally shaped (e.g., square) NW, there is no way to control which side is facing “up” on the substrate after the e-field process.

FIG. 6 is a scanning electron microscope (SEM) image of conventionally produced etched Si NWs showing clumping behavior (prior art). There can several causes of clumping in conventionally-shaped NWs. The first cause occurs after the NWs are released from the buried oxide (by a VHF etch/undercut process). Because the NWs have a small diameter, they do not have enough structural rigidity to avoid bending. This bending can lead to the central portion of adjacent NWs being stuck together by van der Waals forces (see FIG. 7B). The subsequent deposition of the a-Si outer shell electrode material then fully coats the joined NWs. This can lead to nonuniformities in the e-field coating process, and/or electrical shorts in completed devices. Likewise, coated NWs can sometimes clump together during the harvest (FIG. 6) or coating process (see FIG. 8B), which leads to hidden reentrant regions beneath the NWs that can leave behind unetched materials that cause electrical stringers.

It would be advantageous if a NW transistor could be fabricated in a way that alleviated the problems of adjacent NWs sticking to each other before the deposition of an outer shell, and the clumping of NWs during e-field coating.

It would be advantageous if a NW transistor could be made with wider source and drain regions, to provide better e-field coating uniformity.

### SUMMARY OF THE INVENTION

Disclosed herein is a narrow-waist or “dogbone” shaped nanowire (NW) transistor that solves many of the above-mentioned problems by modifying the shape of an etched NW. With this shape, the source and drain regions are wider than the channel region of the NW by a factor of greater than 1, and typically less than 3. This wider source and drain provides better coverage over the e-field electrodes to ensure that only a single NW is deposited during the coating process. The wider source and drain permit larger contact holes and better contact resistance between the NW and a final metal stack. Further, the shape ensures greater uniformity in the side of NW is facing “up” on the substrate after fabrication, and permits multiple NWs to be grouped together and deposited uniformly over the substrate.

The narrow-waist shape addresses several issues that are typically encountered with etched, doped, core-shell-shell silicon (Si) NW fabrication. This shape has the following benefits:

1. Alleviation of the sticking of adjacent NWs before the deposition of an outer shell, which can bind NWs and cause electrical shorts.

2. Avoidance of clumping of NWs during e-field coating.

3. Wider source and drain regions provide better e-field coating uniformity.

4. Multiple NW channels can be included in a single structure.

5. Improvement in the contact area and reduction of contact resistance.

Accordingly, a method is provided for forming narrow-waist nanowire (NW) transistors with wide aspect ratio ends. The method provides a semiconductor-on-insulator (SOI) wafer with a top semiconductor layer. The top semiconductor layer is etched to form a first pad, a second pad, and a plurality of narrow-waist semiconductor bridges. Each semiconductor bridge has two ends, each with a first width, attached to the first and second pads, and a mid-section between the ends with a second width, less than the first width. Typically, each bridge has a first width to second width ratio that is greater than about 1 and less than about 3.

The method forms a channel in a center portion of each semiconductor bridge mid-section, a drain (D) interposed between the channel and a semiconductor bridge first end, a source (S) interposed between the channel and a semiconductor bridge second end, and a gate dielectric surrounding the channel and adjacent portions of the source and drain. A gate electrode is formed surrounding the gate dielectric of each semiconductor bridge. The semiconductor bridge ends are etched from the first and second pads, forming a plurality of narrow-waist semiconductor NW transistors.

In one aspect, the channel, source, and drain are fabricated by forming a cap oxide layer overlying the bridge, and photoresist patterning to expose the S/D regions. After implanting the S/D regions with dopant, the cap oxide and the insulator underling each bridge are removed, forming a thermal oxide gate dielectric layer surrounding the channel.

Additional details of the above-described method, a narrow-waist NW transistor, and a transistor with a plurality of NW bridges are provided below.

### BRIEF DESCRIPTION OF THE DRAWINGS

FIGS. 1A and 1B are partial cross-sectional views, and FIG. 1C is a plan view of a narrow-waist nanowire (NW) transistor.

FIG. 2A is a plan view of a first variation of the NW transistor of FIGS. 1A-1C.

FIG. 2B is a plan view of a transistor with a plurality of semiconductor nanowire bridges.

FIGS. 3A to 3D are plan views illustrating steps in the NW transistor fabrication process.

FIG. 4 depicts planar views of various etched NW configurations with different aspect ratios, tapering, and combinations.

FIG. 5 is a plan view of end-in etched end-doped core-shell-shell (ECSS) NWs coated on e-field electrodes.

FIG. 6 is a scanning electron microscope (SEM) image of conventionally produced etched Si NWs showing clumping behavior (prior art).

FIGS. 7A and 7B are plan views and corresponding transverse cross-sectional views of NWs during the fabrication process (prior to harvest) contrasting, respectively, the narrow-waist shape with a conventional NW shape.

FIGS. 8A and 8B are plan views and corresponding transverse cross-sectional views contrasting, respectively, narrow-waist and conventional shape NWs.

FIG. 9 is a flowchart illustrating a method for forming narrow-waist NW transistors with Wide aspect ratio ends.

### DETAILED DESCRIPTION

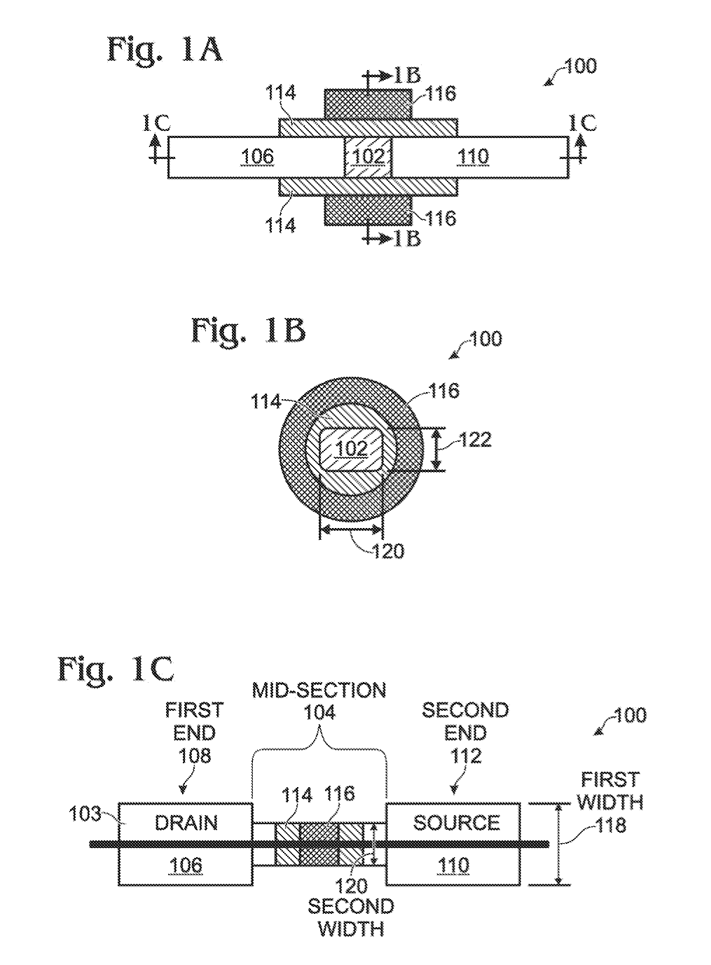

FIGS. 1A and 1B are partial cross-sectional views, and FIG. 1C is a plan view of a narrow-waist nanowire (NW) transistor. The narrow-waist NW transistor 100 comprises a channel 102 formed in a center portion of a semiconductor NW 103 mid-section 104. A drain (D) 106 is interposed between the channel 102 and a first end 108 of the NW. A source (S) 110 interposed between the channel 102 and a second end 112 of the NW. A gate dielectric 114 surrounds the channel 102 and adjacent portions of the source 110 and drain 106. A gate electrode 116 surrounds the gate dielectric 114.

The first NW end 108 and second NW end 112 each have a first width 118, and the NW mid-section 104 has a second width 120, less than the first width 118. In one aspect, the first width 118 is in the range of 8 to 800 nanometers (nm), and the second width 120 is in the range of 3 to 400 nm. In another aspect, the ratio of the first width 118 to the second width 120 is greater than about 1 and less than about 3. However, the NW widths are not limited to any particular ratio, as long as the second width 120 is less than the first width 118.

The semiconductor NW 103 may be silicon, germanium, or silicon/germanium. However, other semiconductor materials are also possible. The gate electrode 116 is a semiconductor material such as silicon, germanium, or silicon/germanium, or a metal such as Ti, Mo, Ta, or W. Again, other semiconductor and metal materials are possible. In one example, the semiconductor NW 103 is silicon and the gate electrode 116 is amorphous silicon.

Typically, the channel 102, source 110, and drain 106 regions have a thickness 122, orthogonal to the first width 118 and second width 120, of less than about 200 nm. As shown in FIG. 1C, the NW 103 may have a rectangular-shaped cross-section, orthogonal to the first width 118 and second width 120. However, other cross-sectional shapes and thicknesses are possible.

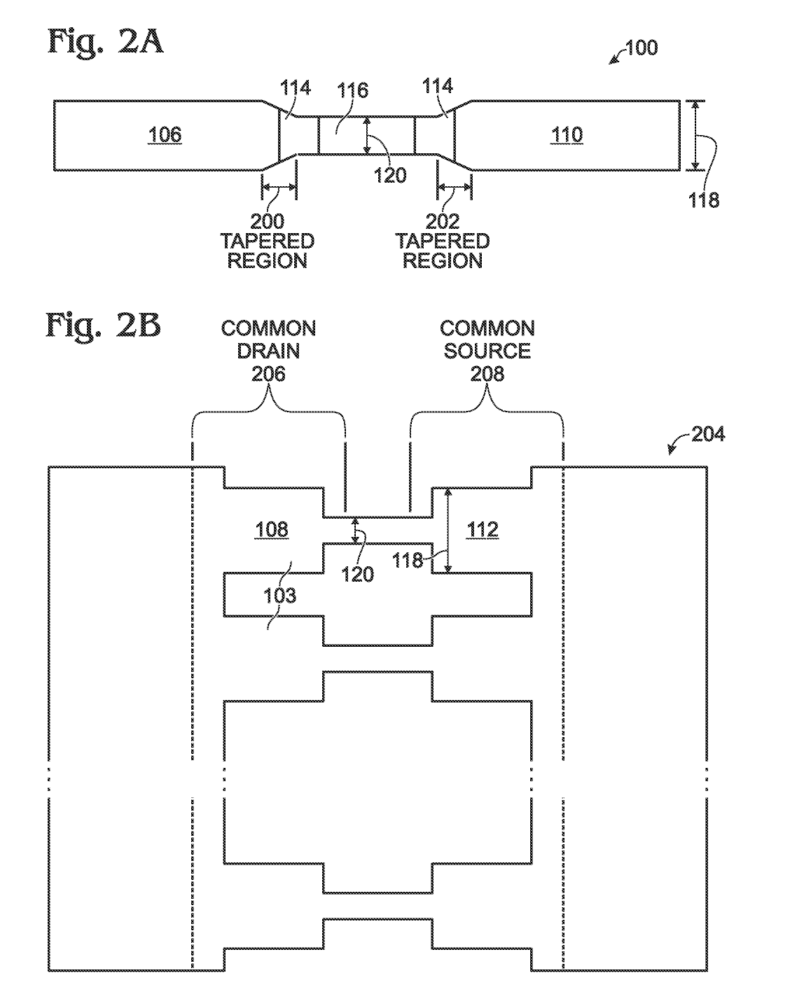

FIG. 2A is a plan view of a first variation of the NW transistor of FIGS. 1A-1C. In this aspect the source 110 includes a first tapered region 200 transiting between the first width 118 and the second width 120. Likewise, the drain 106 includes a second tapered region 202 transiting between the first width 118 and the second width 120. Note: the dielectric 114 need not necessarily be formed in the tapered sections.

FIG. 2B is a plan view of a transistor with a plurality of semiconductor nanowire bridges. In this aspect, a narrow-waist multi-nanowire (NW) transistor 204 is formed. The narrow-waist multi-NW transistor 204 comprises a plurality of semiconductor NWs 103. Each semiconductor NW 103 has a first end 108 and a second end 112 with a first width 118, and a midsection with a second width 120 less than the first width. A common drain 206 is formed in a first semiconductor pad 208 and each semiconductor NW first end 108. A common source 210 is formed in a second semiconductor pad 212 and each semiconductor NW second end 112. Although not explicitly depicted in this figure (see FIGS. 1A-1C), each semiconductor NW 103 includes a channel formed in a center portion of the semiconductor NW mid-section. A gate dielectric surrounds the channel and adjacent portions of the source 206 and drain 210. A gate electrode surrounds the gate dielectric.

### Functional Description

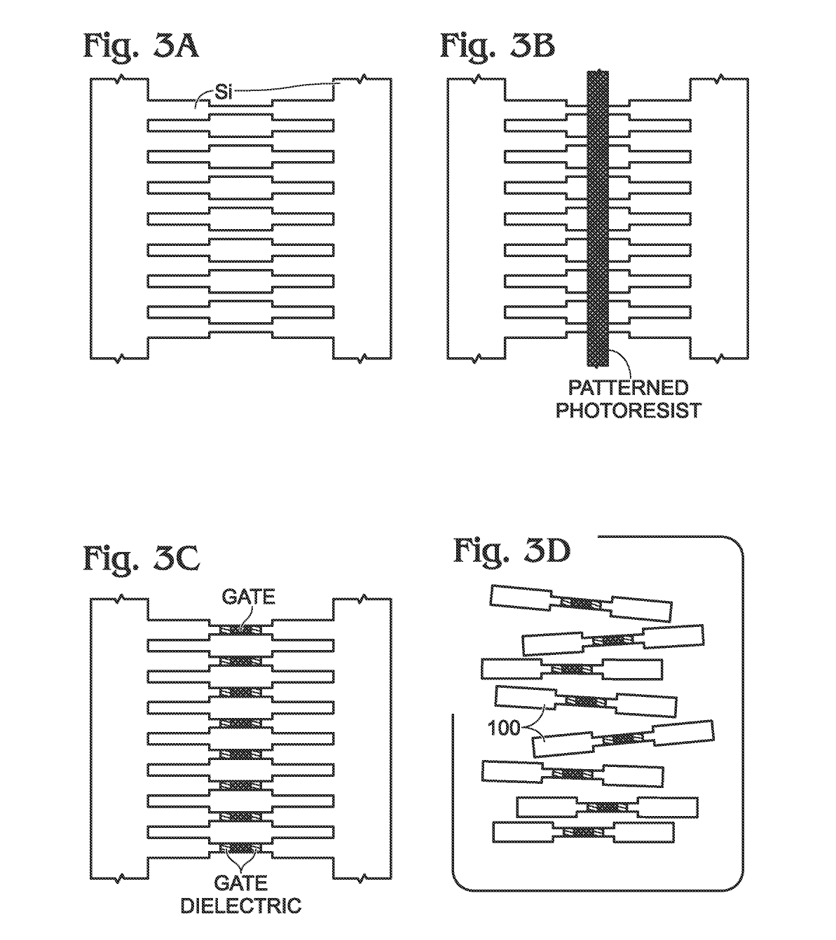

FIGS. 3A to 3D are plan views illustrating steps in the NW transistor fabrication process. In FIG. 3A the Si layer of an SOI wafer is etched. Although only a small area is shown, this patterning can be repeated over an entire wafer. SOI wafers (either SIMOX or bonded) are thinned to the appropriate desired final thickness. In order to avoid high leakage currents, this thickness is typically less than 200 nm, although there is no constraint. A cap oxide of 50 nm can be left in place to act as an implant screen. The narrower portion in the center of the bridges will become the channel region. Wider adjacent regions, which will become the source and drain, are pinned to the bars or pads that hold the NWs in place during the process. The wafers are patterned and the Si layer is etched through the entire thickness, leaving only the regions that will become NWs and adjacent structure to hold the NWs in place during the process steps. Typical NW widths for the channel region are approximately 3-400 nm, leading to source and drain widths of 6-800 nm.

FIG. 3B shows the NW structures after patterning (to cover the channel) and the exposed source/drain regions are implanted with dopant. This can be done using one of two possible approaches. In the first approach, the SOI wafer is patterned and implanted before forming the gate insulator shell. After implant, the photoresist is stripped, and the cap and buried oxides are removed with a vapor HF (VHF) etch process. After VHF, a thermal oxide is grown to form the gate insulator shell. This also activates the source and drain region. Alternatively, the buried oxide can be removed with a VHF etch process and a thermal oxide shell is grown to form the gate insulator shell. The wafer is then patterned and implanted to form the source and drain regions of the device. After implant the photoresist is stripped and the wafer can be thermally annealed to activate the source and drain regions. After implant and the formation of a thermal oxide shell, a doped a-Si layer is deposited to form an outer shell electrode. This electrode has moderate step coverage and fully surrounds the channel region of the NW. The wafers are thermally annealed to activate the outer shell electrode material.

FIG. 3C shows the NW structures after the Si outer shell electrode material is deposited and end-in etched with XeF2. After activation, the wafers are patterned for the release etch. The outer shell electrode is etched from the end using an isotropic XeF2 etch process. This allows the formation of a specific gate electrode length that covers the channel and a small portion of the source and drain regions. Following the XeF2 etch, the pinning structures that hold the NWs in place are etched using an anisotropic etch process.

FIG. 3D shows the harvested NW structures 100. The NWs are harvested from the wafer by removing the photoresist that holds the NWs and sonicating the wafers to release the NWs into a solvent ink. The widened source and drain regions avoid several issues of the standard NW configuration; which have a constant diameter throughout the entire length of the NW.

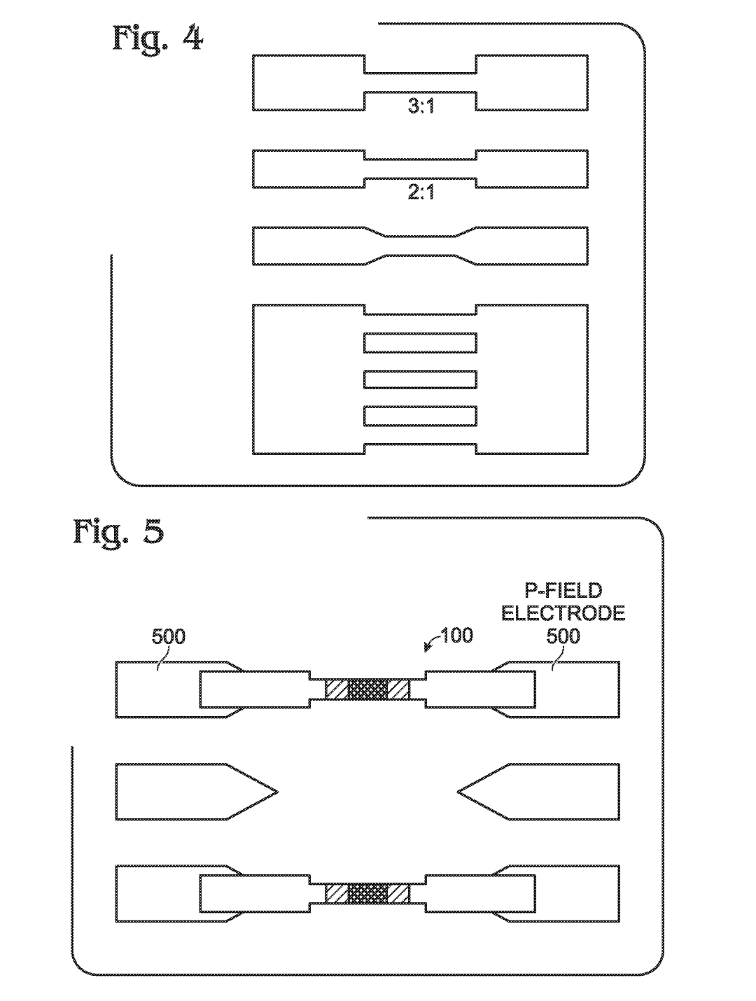

FIG. 4 depicts planar views of various etched NW configurations with different aspect ratios, tapering, and combinations. The top structure has a 3:1 aspect ratio between source/drain and channel, while the second structure has a 2:1 aspect ration. The third structure is a filleted or tapered structure, while the bottom structure depicts a multi-wire configuration with 4 discrete channels being connected to common source and drain regions.

FIG. 5 is a plan view of end-in etched end-doped core-shell-shell (ECSS) NWs coated on e-field electrodes 500. The narrow-waist NW transistor can be distinguished from a conventional etched NW structure based upon the shape of the etched NW. With a narrow-waist shape, the source and drain regions are wider than the channel region of the NW by a factor of 2-5, or as shown in FIG. 4, by 2:1 or 3:1 ratios. In another aspect (see FIG. 2A) there is a filleted transition between the wider source/drain regions and the channel to minimize stress gradients encountered during NW harvest (e.g., during sonication) so that they do not cause cleaving of the Si at this potentially abrupt interface. The wider source and drain also provide better coverage over the e-field electrodes to ensure that only a single NW is deposited during the coating process. Further, the wider source/drain permit larger contact holes and lower contact resistance between the NW and a final metal stack, provide better uniformity in the side of the NW that ultimately faces “up” on the substrate, and permit multiple NWs to be grouped together and deposited uniformly over the substrate. In some aspects, the wider S/D regions (i.e. first width 118, see FIGS. 1A and 1B) are approximately the same width as the e-field electrodes.

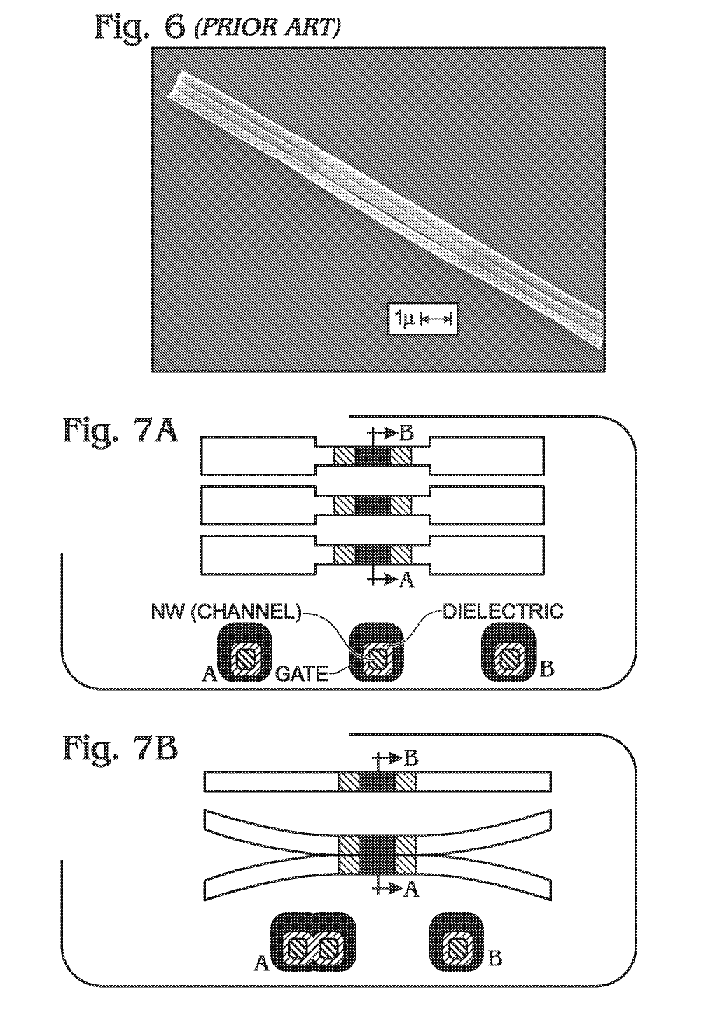

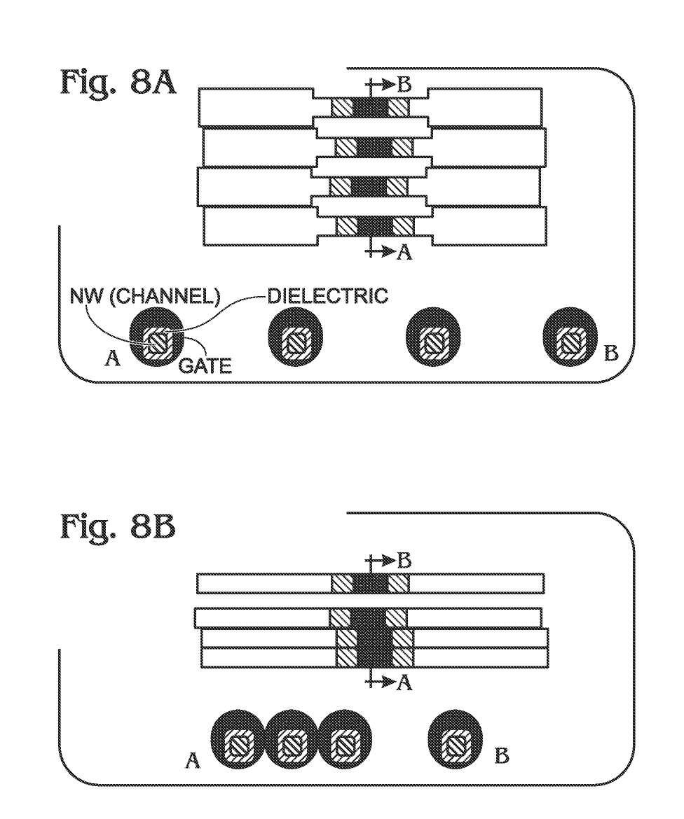

Because conventional NWs have a small diameter, they do not have enough structural rigidity to avoid bending after the NWs are released from the buried oxide (by a VHF etch/undercut process). This bending can lead to the central portion of adjacent NWs being stuck together by van der Waals forces (see FIG. 7B). The subsequent deposition of the a-Si outer shell electrode material then fully coats the joined NWs. This can lead to nonuniformities in the e-field coating process, and/or electrical shorts in completed devices. The incorporation of the dogbone structure eliminates the possibility of the central region of adjacent NWs becoming stuck together. Likewise, coated NWs can sometimes clump together during the harvest (see FIG. 6) or coating process (see FIG. 8B), which leads to hidden reentrant regions beneath the NWs that can leave behind unetched materials that causes electrical stringers. Again, the inclusion of the dogbone structure can be used to avoid the lateral clumping of the NWs and the resulting hidden reentrant pockets.

FIGS. 7A and 7B are plan views and corresponding transverse cross-sectional views of NWs during the fabrication process (prior to harvest) contrasting, respectively, the narrow-waist shape with a conventional NW shape. The cross-sectional views show approximate step coverage of the outer shell electrode material and the effect of NW clumping on step coverage during the fabrication process. For the conventionally shaped NWs, van der Waals forces can cause the wires to stick together in the center. This typically occurs after release and prior to conductive electrode shell deposition, causing the outer shell electrode to encompass multiple adjacent NWs, in addition to having less uniform step coverage (with the possibility of no coverage at the point indicated by the arrow in FIG. 7B). After release, these clumped NWs are impossible to separate and lead to non-uniformities in the coating process and potentially electrically-shorted devices. This is avoided with the “dogbone” shaped NWs that force a space between the channel regions of adjacent NWs, as well as providing more structural rigidity that can avoid the lateral bending of the NWs.

FIGS. 8A and 8B are plan views and corresponding transverse cross-sectional views contrasting, respectively, narrow-waist and conventional shape NWs. For the conventionally shaped NWs, clumping can lead to hidden reentrant regions (indicated by the arrows in FIG. 8B) that can cause problems with later processing steps and/or the formation of electrical stringers. This is avoided with the “dogbone” or narrow-waist shaped NWs that force a space between the channel regions of adjacent NWs.

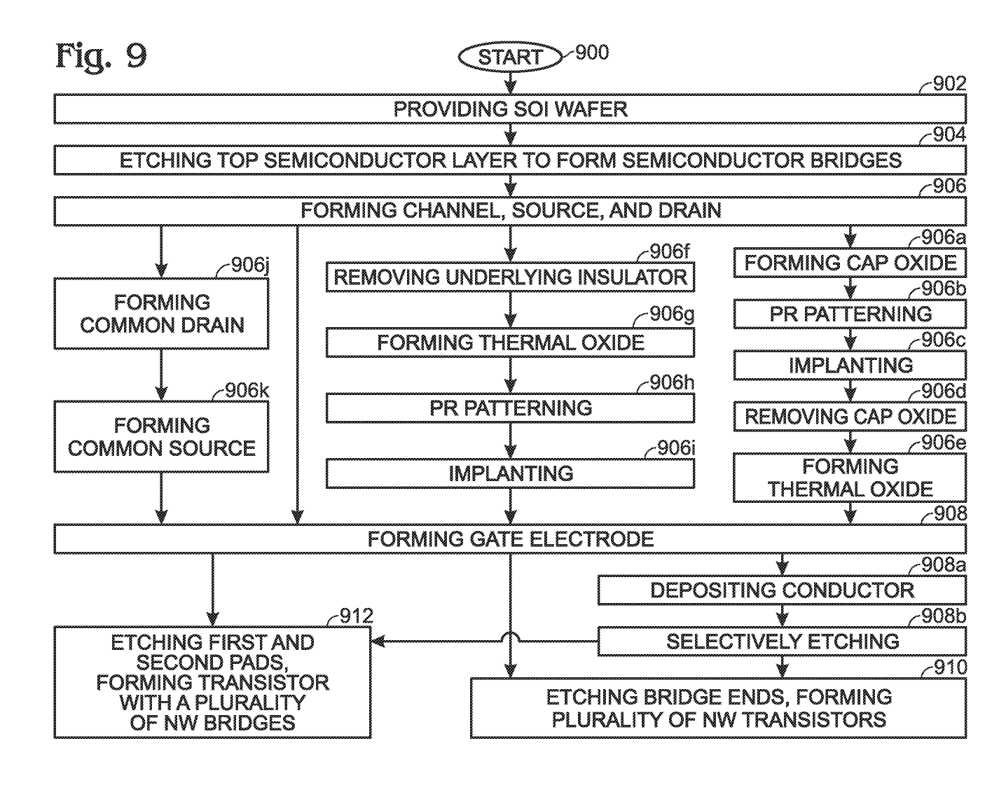

FIG. 9 is a flowchart illustrating a method for forming narrow-waist NW transistors with wide aspect ratio ends. Although the method is depicted as a sequence of numbered steps for clarity, the numbering does not necessarily dictate the order of the steps. It should be understood that some of these steps may be skipped, performed in parallel, or performed without the requirement of maintaining a strict order of sequence. Generally however, the method follows the numeric order of the depicted steps. The method starts at Step 900.

Step 902 provides a semiconductor-on-insulator (SOI) wafer with a top semiconductor layer. The semiconductor may be silicon, germanium, or silicon/germanium, for example. In one aspect, the top semiconductor layer has a thickness of less than about 200 nm. Step 904 etches the top semiconductor layer to form a first pad, a second pad, and a plurality of narrow-waist semiconductor bridges. Each semiconductor bridge has two ends, each with a first width, attached to the first and second pads, and a mid-section between the ends with a second width, less than the first width. In one aspect, the bridge first widths are in the range of 8 to 800 nm, and the bridge second widths are in the range of 3 to 400 nm. In another aspect, each bridge has a first width-to-second width ratio that is greater than about 1 and less than about 3. In one variation, each semiconductor bridges forms a first tapered region in the source transiting between the first width and the second width, and a second tapered region in the drain transiting between the first width and the second width.

Step 906 forms a channel in a center portion of each semiconductor bridge mid-section, a drain (D) interposed between the channel and a semiconductor bridge first end, and a source (S) interposed between the channel and a semiconductor bridge second end. Step 906 also forms a gate dielectric surrounding the channel and adjacent portions of the source and drain. Step 908 forms a gate electrode surrounding the gate dielectric of each semiconductor bridge.

In one aspect, forming the channel, source, and drain in each bridge includes the following substeps. Step 906a forms a cap oxide layer overlying the bridge. Step 906b photoresist (PR) patterns to expose the S/D regions. Step 906c implants the S/D regions with dopant, and Step 906d removes the cap oxide and the insulator underling each bridge. Step 906e forms a thermal oxide gate dielectric layer surrounding the channel.

Alternatively, Step 906f removes the insulator underlying each bridge. Step 906g forms a thermal oxide gate dielectric layer surrounding the channel. Step 906h photoresist patterns to expose the S/D regions. Step 906i implants dopant into the S/D regions.

A cap oxide is sometimes used as a screen for ion implant in order to optimize the depth and dose of the implanted dopant. However, implanting can be performed with or without a screen, so it's optional, depending on the NW configuration. A screen oxide is used in Steps 906f-906i, albeit in the form of the thermal oxide grown after the VHF undercut step. One advantage to the approach of Steps 906a-906e is that since the thermal oxide is formed after the implant and undercut, there is no implant damage to the thermal oxide. Further, this approach minimizes the number of PR/pattern steps on the free-standing NWs. As bridge structures, the NWs are more prone to breakage due to the forces associated with spin coating.

The channel can be doped prior to patterning the top Si layer, or left undoped as needed. Since this doping is usually for affecting the threshold voltage shift, the doping level is typically very low and can be done as a blanket implant.

In one aspect, forming the gate electrode in Step 908 includes the following substeps. Step 908a deposits a conductor overlying each bridge. Step 908b selectively etches to remove the conductor overlying the S/D regions, leaving in place the conductor overlying the channel. The gate electrode can be made from a material such as silicon, germanium, silicon/germanium, Ti, Mo, Ta, or W. Step 908b may use xenon difluoride (XeF₂) to selectively etch.

Step 910 etches the semiconductor bridge ends from the first and second pads, forming a plurality of narrow-waist semiconductor NW transistors. PR is deposited and patterned prior to the release etch. An end-in etch of the NWs may be performed using an isotropic etchant (e.g., XeF2), while still keeping the NWs attached at the ends in the core and inner shell oxide. Then, Step 910 etches the ends of the NWs using an anisotropic etch to release the NWs from the pads or “busbars” that hold the ends.

As an alternative to forming independent NW transistor structures, forming the drain and source in Step 906 may include the following substeps. Step 906j forms a common drain region in a plurality of adjacent semiconductor NWs first ends and in the first pad adjacent the semiconductor NWs. Step 906k forms a common source region in a plurality of adjacent semiconductor NWs second ends and in the second pad adjacent the semiconductor NWs. Then, as an alternative to Step 910, Step 912 etches the first and second pads to form a transistor with a plurality of narrow-waist semiconductor bridges.

A narrow-waist NW transistor and associated fabrication process have been presented. Examples of particular shapes, materials, and process flows have been presented to illustrate the invention. However, the invention is not limited to merely these examples. Other variations and embodiments of the invention will occur to those skilled in the art.

We claim:

1. A method for forming narrow-waist nanowire (NW) transistors with wide aspect ratio ends, the method comprising:
providing a semiconductor-on-insulator wafer with a top semiconductor layer;
etching the top semiconductor layer to form a first pad, a second pad, and a plurality of narrow-waist semiconductor bridges, each semiconductor bridge having two ends, each with a first width, attached to the first and second pads, and a mid-section between the ends with a second width, less than the first width;
forming a channel in a center portion of each semiconductor bridge mid-section, a drain (D) interposed between the channel and a semiconductor bridge first end, a source (S) interposed between the channel and a semiconductor bridge second end, and a gate dielectric surrounding the channel and adjacent portions of the source and drain; and,
forming a gate electrode surrounding the gate dielectric of each semiconductor bridge.

2. The method of claim 1 wherein forming the semiconductor bridges includes forming bridge first widths in a range of 8 to 800 nanometers (nm), and bridge second widths in a range of 3 to 400 nm.

3. The method of claim 1 wherein forming the semiconductor bridges includes forming each bridge with a first width to second width ratio that is greater than about 1 and less than about 3.

4. The method of claim 1 wherein forming the channel, source, and drain in each bridge includes:
forming a cap oxide layer overlying the bridge;
photoresist patterning to expose the S/D regions;
implanting the S/D regions with dopant;
removing the cap oxide, and the insulator underling each bridge; and,
forming a thermal oxide gate dielectric layer surrounding the channel.

5. The method of claim 1 wherein forming the channel, source, and drain in each bridge includes:
removing the insulator underlying each bridge;
forming a thermal oxide gate dielectric layer surrounding the channel;
photoresist patterning to expose the S/D regions; and,
implanting dopant into the S/D regions.

6. The method of claim 1 wherein forming the gate electrode surrounding the gate dielectric of each semiconductor bridge includes:
depositing a conductor overlying each bridge; and,
selectively etching to remove the conductor overlying the S/D regions, leaving in place the conductor overlying the channel.

7. The method of claim 6 wherein forming the gate electrode includes forming the gate electrode from a first material selected from a group consisting of silicon, germanium, silicon/germanium, Ti, Mo, Ta, and W.

8. The method of claim 7 selectively etching to remove the first material includes using a xenon difluoride (XeF₂) etchant.

9. The method of claim 1 further comprising:
etching the semiconductor bridge ends from the first and second pads, forming a plurality of narrow-waist semiconductor NW transistors.

10. The method of claim 9 wherein etching the semiconductor bridge ends includes anisotropically etching the bridge ends.

11. The method of claim 1 wherein providing the semiconductor-on-insulator wafer includes providing a semiconductor-on-insulator wafer with a semiconductor selected from a group consisting of silicon, germanium, and silicon/germanium.

12. The method of claim 1 wherein etching to form the plurality of semiconductor bridges includes forming a first tapered region in the source transiting between the first width and the second width, and a second tapered region in the drain transiting between the first width and the second width.

13. The method of claim 1 wherein providing the semiconductor-on-insulator wafer with the top semiconductor layer includes providing a top semiconductor layer having a thickness of less than about 200 nm.

14. The method of claim 1 wherein forming the drain and source includes:
forming a common drain region in a plurality of adjacent semiconductor NWs first ends, and in the first pad adjacent the semiconductor NWs;
forming a common source region in a plurality of adjacent semiconductor NWs second ends, and in the second pad adjacent the semiconductor NWs; and,
the method further comprising:
etching the first and second pads to form a transistor with a plurality of narrow-waist semiconductor bridges.

15. A narrow-waist nanowire (NW) transistor comprising:
a channel formed in a center portion of a semiconductor NW mid-section;
a drain (D) interposed between the channel and a first end of the NW;
a source (S) interposed between the channel and a second end of the NW;
a gate dielectric surrounding the channel and adjacent portions of the source and drain;
a gate electrode surrounding the gate dielectric; and,
wherein the first and second NW ends have a first width, and the NW mid-section has a second width, less than the first width.

16. The NW transistor of claim 15 wherein the first width is in a range of 8 to 800 nanometers (nm), and the second width is in a range of 3 to 400 nm.

17. The NW transistor of claim 15 wherein the ratio of the first width to the second width is greater than about 1 and less than about 3.

18. The NW transistor of claim 15 wherein the NW has a rectangular-shaped cross-section, orthogonal to the first and second widths.

19. The NW transistor of claim 15 wherein the source includes a first tapered region transiting between the first width and the second width; and,
wherein the drain includes a second tapered region transiting between the first width and the second width.

20. The NW transistor of claim 15 wherein semiconductor NW is a semiconductor selected from a group consisting of silicon, germanium, and silicon/germanium; and,
wherein the gate electrode is a material selected from a group consisting of silicon, germanium, silicon/germanium, Ti, Mo, Ta, and W.

21. The NW transistor of claim 15 wherein the channel, source, and drain regions have a thickness, orthogonal to the first and second widths, of less than about 200 nm.

22. A narrow-waist multi-nanowire (NW) transistor comprising:
a plurality of semiconductor NWs, each semiconductor NW having a first end and a second end with a first width, and a midsection with a second width less than the first width;
a first semiconductor pad;
a common source formed in the first semiconductor pad and each semiconductor NW first end;
a second semiconductor pad;
a common drain formed in the second semiconductor pad and each semiconductor NW second end;
wherein each semiconductor NW includes:
a channel formed in a center portion of the semiconductor NW mid-section;
a gate dielectric surrounding the channel and adjacent portions of the source and drain; and,
a gate electrode surrounding the gate dielectric.
